(19) United States
(12) Patent Application Publication
(10) Pub. No.: US 2015/0142350 A1
(43) Pub. Date: May 21, 2015

(54) METHOD AND DEVICE FOR ESTIMATING POWER CONSUMPTION

(71) Applicant: Xerox Corporation, Norwalk, CT (US)

(72) Inventors: Fritz Francis Ebner, Pittsford, NY (US); Yves Hoppenot, Nortre Dame de Mesage (FR)

(73) Assignee: Xerox Corporation, Norwalk, CT (US)

(21) Appl. No.: 14/084,947

(22) Filed: Nov. 20, 2013

(51) Int. Cl. G01R 21/133; H04L 12/26

(52) U.S. Cl. CPC G01R 21/1333; H04L 43/103
USPC 702/62

(57) ABSTRACT

A method and device for polling a device such as a multifunction printing device. For example, the method includes sending a first polling request to a device to be polled after an elapsed first period of time, receiving a first polling response from the polled device, determining a mode the polled device is operating in based upon the first polling response, and if the polled device is operating in a high power state, sending a second polling request to the polled device after an elapsed second period of time. The method can further include receiving a second polling response from the polled device, determining a mode the polled device is currently operating in based upon the second polling response, and if the polled device is operating in a high power state, sending a third polling request to the polled device after an elapsed second period of time.

### BACKGROUND

The present disclosure relates to estimating power consumption. More specifically, the present disclosure relates to estimating power consumption for a print device.

Energy consumption reporting and control for a device, such as an office device, is becoming more interesting to consumers. As electricity becomes more expensive, and consumers strive to become more environmentally conscious, accurate power consumption and modeling is becoming more important.

Many office devices such as printers, copiers and multifunction devices (e.g., a single device capable of scanning, printing, faxing and/or copying) are capable of operating in one or more states. For example, when a device is not used for a given period of time, the device may enter a “sleep” state. During a sleep state, various components in the device go into low power operation or are turned off completely. Once the device receives a request to perform a specific function, the device may exit the sleep state and operate as normal.

Existing techniques for energy estimation use a variety of methods, each having differing accuracy and precision. Some estimation techniques require polling a device to acquire the current state of the device. For example, a printing device may be in a high energy state such as printing, or a low energy state such as idle or sleep modes. When a printing device responds to a polling request indicating its current state, the polling device lists the responding device as being in that state until the next poll, even though the device may only be in that state for a small percentage of the polling period.

To continue the print device example, a polling device may poll a print device every 30 minutes. If the print device responds that it is in print mode, the polling device will list the printing device as being in print mode until the next poll. Printing at a print device typically consumes a high amount of power for a short amount of time. Thus, existing polling techniques produce a high error value as the entire polling period is set to a high power state such as printing, even though the polled device may only be in that high power state for a small percentage of the time period.

### SUMMARY

In one general respect, the embodiments disclose a method of polling a device. The method includes send a first polling request to a device to be polled after an elapsed first period of time, receiving a first polling response from the device to be polled, determining a mode the device to be polled is currently operating in based upon the first polling response, and if the device to be polled is operating in a high power state, sending a second polling request to the device to be polled after an elapsed second period of time, wherein the second period of time is shorter than the first period of time.

In another general respect, the embodiments disclose a system for polling a device. The system includes a processing device and a non-transitory computer readable medium in communication with the processing device. The computer readable medium includes one or more programming instructions for causing the processing device to send a first polling request to a device to be polled after an elapsed first period of time, receive a first polling response from the device to be polled, determine a mode the device to be polled is currently operating in based upon the first polling response, and if the device to be polled is operating in a high power state, send a second polling request to the device to be polled after an elapsed second period of time, wherein the second period of time is shorter than the first period of time.

### BRIEF DESCRIPTION OF THE DRAWINGS

FIG. 1 depicts a sample flow diagram of an improved polling method according to an embodiment.

FIG. 2 depicts a sample power state graph and a polling timing diagram according to existing polling techniques.

FIG. 3 depicts a sample power state graph and an updated polling timing diagram according to an embodiment.

FIG. 4 depicts a sample flow diagram for a process of using state transition log information to improve power estimation during polling according to an embodiment.

FIG. 5 depicts a power consumption and polling timing diagram according to an embodiment.

FIG. 6 depicts various embodiments of a computing device for implementing the various methods and processes described herein.

### DETAILED DESCRIPTION

This disclosure is not limited to the particular systems, devices and methods described, as these may vary. The terminology used in the description is for the purpose of describing the particular versions or embodiments only, and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to.”

As used herein, a “device” refers to an electronic device configured to perform one or more specific functions. Each device has an associated power model that defines the device's power consumption during certain states as well as the device's power consumption during transitions between certain states.

A “power model” refers to an estimated representation of power usage for a specific device. If the device is a multifunction device configured to operate in multiple states, the power model includes power consumption levels for each of the multiple states as well as power consumption information for transitioning between from one state to another. A power model may be provided by the manufacturer of a device, or determined by measuring the power consumption of the device as it operates.

A “printing device” refers an electronic device that is capable of receiving commands, and/or printing text characters and/or images on a substrate, and/or scanning images. Printing devices may include, but are not limited to, network printers, production printers, copiers and other devices using ink or toner, and scanners. A printing device may also perform a combination of functions such as printing and scanning, in which case such a device may be considered a multifunctional device.

A “state transition log” or a “power state log” refers to a record of state transitions at a printing device, as well as timing information between the state transitions. For example, a power state log may indicate at what time a print device transitioned to a print state, and at what time the print device exited the print state and entered an idle state.

A “computing device” refers to a device that processes data in order to perform one or more functions. A computing device may include any processor-based device such as, for example, a server, a personal computer, a personal digital assistant, a web-enabled phone, a smart terminal, a dumb terminal and/or other electronic device capable of communicating in a networked environment. A computing device may interpret and execute instructions.

The present disclosure is directed to a method of estimating power consumption at a device, such as an office printing device, based upon a dynamic polling schedule that may be altered or changed based upon results received from a particular poll.

Typical printing devices spend a large percentage of time in lower power states such as idle or sleep states, having a typically less than 10% utilization rate. As indicated above, existing polling techniques use a static polling period when polling various devices. If a polled device indicates that it is currently in a high power state, the polling device records the polled device as being in the high power state for the entire polling period. This type of polling technique can lead to large errors, however, as the polled device may only be in the high power state for a small percentage of the polling period.

The method and process as described herein provides a polling technique that uses dynamic polling periods. For example, if the polling device receives an indication that the polled device is in a high power state, the polling device may reduce the polling period to a short period of time, and continually poll the device until the polled device responds that it is operating in a low power state. The polling device may then rest the polling period to the original length of time, and continue polling the polled device at the original intervals.

It should be noted that, as used herein, a high power state refers to a state where a specific device is using a higher amount of power when compared to the amount of power the devices uses when in an idle or sleep mode. Conversely, a low power state refers to a state where a specific device is using about the average amount of power it uses during is idle or sleep mode, e.g., the amount of power the device typically uses when not performing a specific job. For example, a printing device is typically operating in an idle or sleep mode. As used herein, idle or sleep modes would be considered low power states for a printing device. Alternatively, print mode would be considered a high power state for the print device, as the print device uses a much larger amount of power during that mode when compared to idle or sleep modes.

To determine whether a device is operating in a high or low power state, a monitoring device may categorize the various modes of the device being monitored as either high power or low power prior to monitoring the device. For example, for a multi-function print device, scanning, copying and printing modes may be categorized as high power states, while emailing, faxing, idle and sleep modes may be categorized as low power states. Alternatively, the monitoring device may use a particular threshold to delineate between the two modes. For example, a printing device may use 900 Watts when in print mode, 80 watts when in idle mode, and 5 Watts when in sleep mode. For this device, the delineation threshold may be set at 100 Watts such that any mode above 100 Watts is considered a high power state, and any mode below 100 Watts may be considered a low power state. It should be noted that this delineation method is shown by way of example only, and determining if a device is operating in a high power state or a low power state may vary based upon the device doing the monitoring as well as the operational modes of the device being monitored.

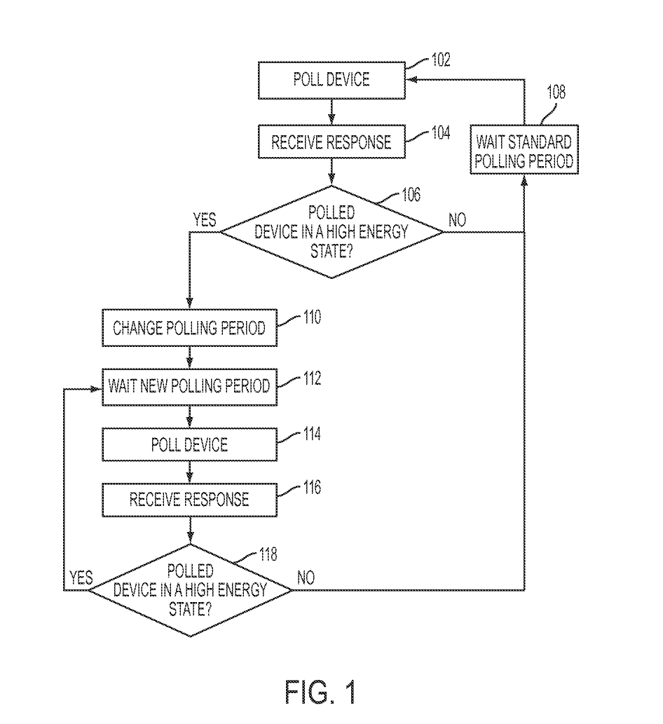

FIG. 1 depicts an improved polling process for estimating power consumption by a device using dynamic polling periods. It should be noted that the process as shown in FIG. 1 is directed to a print device by way of example only.

Initially, a polling device such as a monitoring computer polls 102 a print device, and receives 104 a response from the print device. In this example, the poll may include a request for the print device to reply with an indication of what mode the print device is currently operating in. T print device may generate and transmit a response to the monitoring computer indicating what mode the print device is currently operating in. Based upon the response, the monitoring computer may determine 106 whether the polled printing device is operating in a high energy state.

To determine 106 if the polled print device is in a high energy state, the monitoring computer may access an associated power model or other similar information to determine whether the response form the print device indicates a high energy state. For example, if the print device responds that it is currently operating in an idle mode, the monitoring computer may determine 106 that the printing device is not in a high energy mode based upon the power model associated with the print device. Alternatively, the monitoring computer may follow a set of rules for all print devices. For example, if a print device is currently printing, it is in a high power state. For any other non-printing modes, the print device is in a low power state.

If the monitoring computer determines 106 that the polled device is not in a high energy state, the polling device may update a data log related to the operation of the polled device, and wait 108 a standard polling period until polling 102 the device again.

Conversely, if the monitoring computer determines 106 the polled device is operating in a high energy state, the monitoring computer may change 110 the polling period such that the polled device is polled at a higher frequency. For example, the monitoring device may change 110 the polling period from 30 minutes to one minute. Alternatively, the monitoring computer may determine a shortened polling period for the polled device based upon historic operational data related to the polled device. For example, if the polled device typically handles large print jobs that last an average of 3 minutes, the monitoring computer may change 110 the polling period to three minutes. Additional historic information such as job frequency may also impact how the monitoring computer changes 110 the polling period.

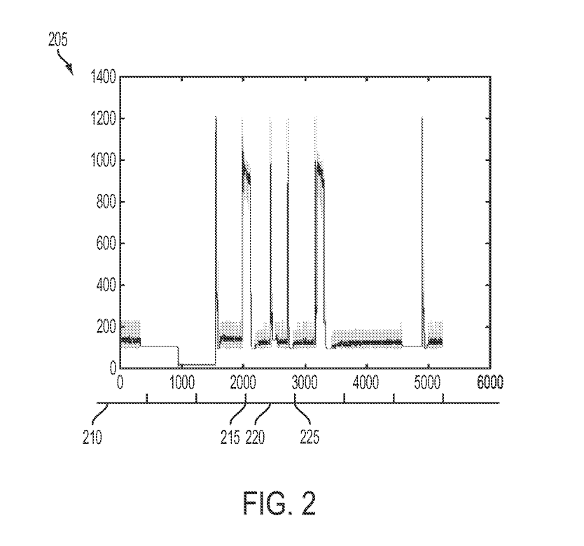

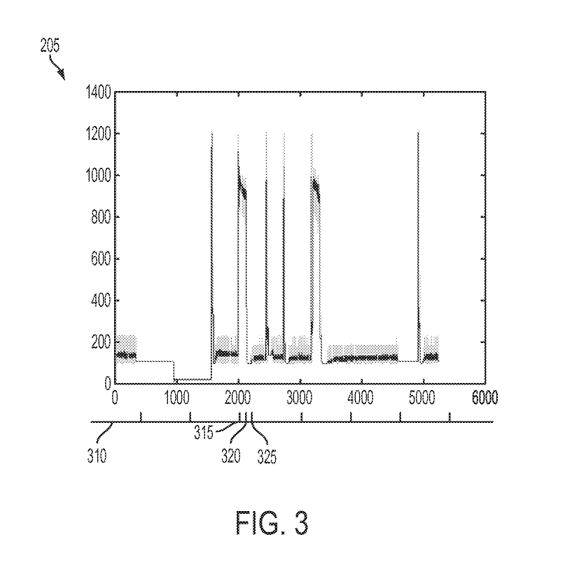

After changing 110 the polling period, the monitoring computer may wait 112 the new polling period before polling 114 the device again. Like before, the monitoring computer may receive 116 a response from the polled device, the response indicating what mode the polled device is currently operating in. Based upon the response, the monitoring computer may determine 118 whether the polled printing device is still operating in a high energy state. If the polled device is not operating in a high energy state, the monitoring computer may wait 108 a standard polling period (to continue the above example, 30 minutes) before polling 102 the device again. Conversely, if the monitoring computer determines 118 that the polled device is still operating in a high energy mode, the monitoring computer may wait 112 the new polling period (e.g., one minute) before polling 114 the device again. This process is further explained below in reference to FIGS. 2 and 3.

It should be noted that the process as shown in FIG. 1 may be continually repeated multiple times over a specific time period in order to accurately estimate the energy consumption at the print device. For example, the polling process may be repeated for a week to obtain an overview of the power consumed by a device over that period of time. Alternatively, the polling process may be repeated every for a shorter period of time, e.g., for 24 hours, depending on the availability of the monitoring computer and the overall usage statistics of the print device being polled and monitored.

Additionally, it should be noted that the polling periods as described in reference to FIG. 1 are shown by way of example only, and additional polling periods may be used. For example, the standard polling period may be one hour, and the new, high frequency polling period may be five minutes. Additionally, the new, high frequency polling period may be device specific (e.g., determined based upon historic performance information for the device as outlined above), or the monitoring computer may use the same polling periods for all devices being monitored.

In estimating energy and power consumption at a device, the frequency of polling may directly impact the accuracy of the results. For example, polling at a greater frequency (e.g., every one minute) may provide more accurate results than polling at a lower frequency (e.g., every 30 minutes). However, polling at a greater frequency may require additional resources at the monitoring computer, thus reducing the overall efficiency of the estimation technique. Conversely, as outlined above, polling infrequently may result in a device being assigned a high power state for an entire polling period, when the device was in the high power state for only a small portion of the polling period.

FIGS. 2 and 3 illustrate a sample set polling time diagrams for a sample power state graph 205. As shown in FIG. 2, polling timing diagram 210 indicates that the device is polled every 30 minutes. As polling point 215, the polled device may respond that it is currently in a print mode, i.e., a high power state. Using conventional techniques, the polled device would be assumed to be printing for the entire polling period 220, until polling point 225 where the polled device would respond that it is operating in a low power state, e.g., idle mode. As shown in FIG. 2, the printing mode only lasts for a small portion of polling period 220, thus leading to a large amount of error when calculating total estimated power consumed as a result of the device being assigned as printing the entire poling period.

FIG. 3 illustrates a polling timing diagram 310 that uses the dynamic polling techniques as described above in FIG. 1. Similar to FIG. 2, at polling point 315 the polled printing device may respond that is it currently in print mode, i.e., a high energy state. The monitoring computer performing the polling may determine that the print device is in a high energy state, and modify the polling period such that the polling points occur at a higher frequency. For example, the monitoring computer may change the polling period from 30 minutes (e.g., as is shown in FIG. 2) to one minute. Thus, polling point 320 occurs one minute after polling point 315. Like polling point 315, the printing device responds that it is operating in print mode at polling point 320. As this is still a high energy state, the monitoring computer may continue to poll at the higher frequency. Like before, polling point 325 may occur one minute after polling point 320. However, at polling point 325 the printing device may indicate it is currently operating in idle mode. The monitoring computer may determine this is a low energy state and revert back to the original polling period frequency, e.g., once every 30 minutes.

It should be noted that the data shown in FIGS. 2 and 3 is shown by way of example only, and based upon the individual types of devices being polled the polling data may vary accordingly.

Additional techniques may be used in combination with the process as described above in regard to FIGS. 1-3 to improve the estimation of power consumption by removing additional error causing factors. For example, beyond merely requesting a current state from a polled device, a polling device may also request a state transition log form the polled device for the time period between the current poll and a previous poll. Based upon the state transition log, the monitoring computer may make a more precise calculation about the power being consumed by the polled device.

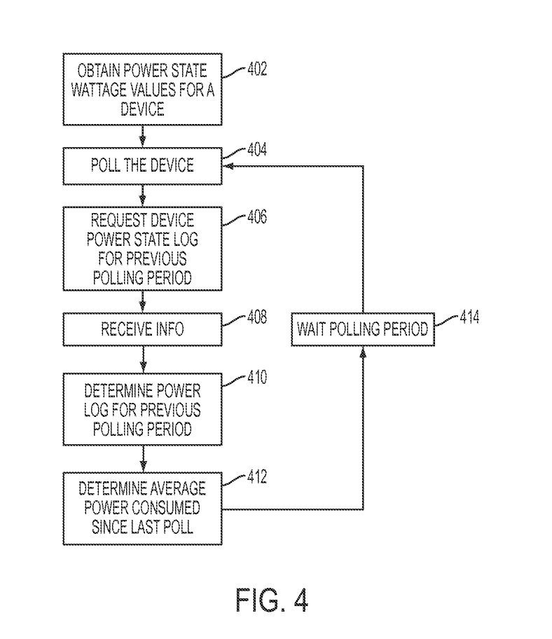

FIG. 4 depicts a process of using state transition log information to improve power estimation during device polling. A monitoring computer, such as the polling device referred to above in reference to FIGS. 1-3, may request and obtain 402 information related to power state wattage values for a particular device being monitored. This information may be obtained directly from the device itself, e.g., the device may transmit a copy of its power model to the monitoring computer. Similarly, the monitoring computer may obtain 402 the information from additional sources, such as the device manufacturer. The monitoring computer may store the information related to the power state wattage values for the device until needed.

The monitoring device may poll 404 the device. Similar to polling as described in FIG. 1, the poll request may include a request for current state information for the polled device. However, the monitoring computer may also request 406 power state log information for the device over the previous polling period. For example, if the polling period is thirty minutes, the monitoring device may request 406 power state log information for the previous thirty minutes of operation of the polled device. The power state log information may include information related to what mode the device was operating in, and at what time the device transitioned into and out of that mode. The monitoring computer may receive 408 the requested info, i.e., a polling response indicating what mode the device is currently operating in, as well as the power state log information.

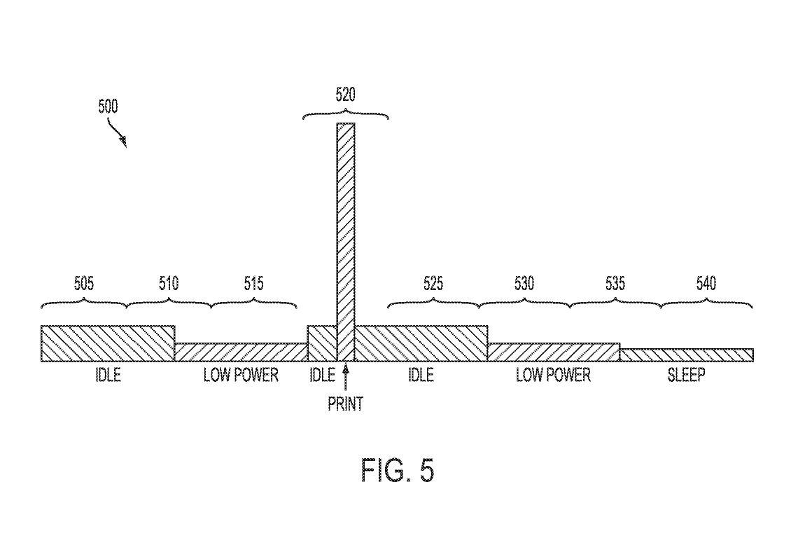

Based upon the power state log information, the monitoring computer may determine 410 a power log for the previous polling period for the device. A power log is a representation of the actual power used for each mode the device may be in, for an appropriate amount of time. FIG. 5 depicts a sample power log 500 for a device, illustrating the power used by the device as it operates in various modes (e.g., idle, low power, print and sleep). As shown in FIG. 5, polling periods 505-540 may occur regularly, or according to a process such as that explained in reference to FIG. 1. At particular polling periods, such as polling periods 510, 520, 530 and 535, the polled device may transition between modes during the polling period. For example, in polling period 520, the device may transition from idle mode to print mode and back to idle mode all during a single polling period.

The monitoring computer may determine 410 by converting the information from the power state log (i.e., what mode was the device operating in and for how long) into actual wattage values based upon the information contained within the power model (i.e., how much power does the device use in each mode per unit of time).

Using the converted power information, the monitoring computer may determine 412 an average power consumed by the device since the last poll period. To determine the average power, the monitoring computer may multiple the change in time for each mode of operation times the average power used by the device in that mode. For example, a monitoring device may poll a printing device every five minutes. During a polling period (such as polling period 520 as shown in FIG. 5), the printing device may initially be in idle mode for three minutes, print mode for 30 seconds, and idle again for one minute and 30 seconds. From the power model, the monitoring computer may determine that the printing device uses 80 watts in idle mode and 900 watts in print mode. To determine 412 the average power, the monitoring computer may first use the following equation:

TE=deltaT1*P1+deltaT2*P2+deltaT3*P3,

where TE is total energy, deltaT1 is the time spent in the first mode, P1 is the power used in the first mode, deltaT2 is the time spent in the second mode, P2 is power used in the second mode, deltaT3 is the time spent in the third mode, and P3 is the power spent in the third mode. It should be noted that three modes are shown by way of example only, and the number of modes would vary based upon the polling period length and the frequency of use of the device being polled.

Substituting in values form the above example, the above equation would read TE=180*80+30*900+90*80, where TE=48600. To determine 412 the average power, the monitoring computer may divide the total energy TE by the total length of the polling period, i.e., 48600/300=162 Watts. Thus, in the above example, the polled device uses an average of 162 Watts during the polling period. However, it should be noted that his is an estimated average of the power used by the polled device over the polling period. More specific equations using the polled devices transition states (e.g., the power required to transition between modes) may be used. However, the equations as shown above are merely for explanatory purposes only.

After determining 412 the average power consumed during the previous polling period, the monitoring computer may wait 414 a polling period before polling 404 the device again.

The processes as described in FIGS. 1 and 4 may be used independently to improve power consumption estimation for a polled device, or used in concert to provide an even higher accuracy estimation technique.

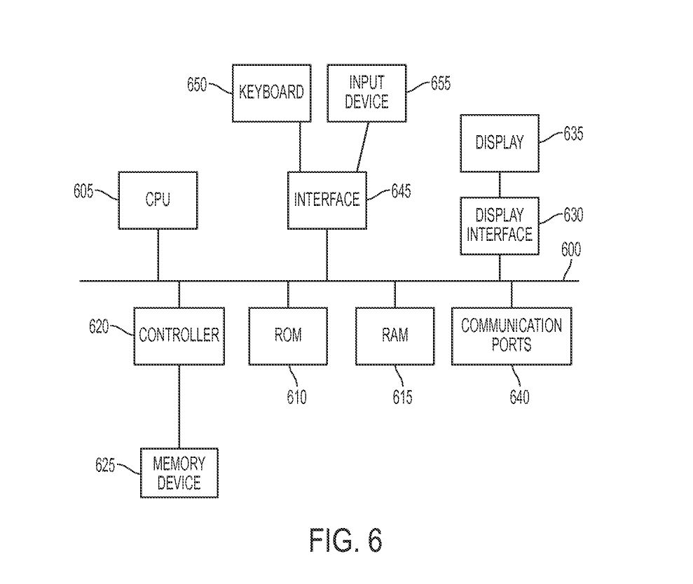

FIG. 6 depicts a block diagram of internal hardware that may be used to contain or implement the various methods and processes as discussed above. An electrical bus 600 serves as the main information highway interconnecting the other illustrated components of the hardware. CPU 605 is the central processing unit of the system, performing calculations and logic operations required to execute a program. For example, CPU 605 may perform the functions performed by the processing device in the above discussion of FIGS. 1 and 4. CPU 605, alone or in conjunction with one or more of the other elements disclosed in FIG. 6, is a processing device, computing device or processor as such terms are used within this disclosure. Read only memory (ROM) 610 and random access memory (RAM) 615 constitute examples of memory devices.

A controller 620 interfaces with one or more optional memory devices 625 to the system bus 600. These memory devices 625 may include, for example, an external or internal DVD drive, a CD ROM drive, a hard drive, flash memory, a USB drive or the like. As indicated previously, these various drives and controllers are optional devices. Additionally, the memory devices 625 may be configured to include individual files for storing any software modules or instructions, auxiliary data, incident data, common files for storing groups of contingency tables and/or regression models, or one or more databases for storing the information as discussed above.

Program instructions, software or interactive modules for performing any of the functional steps associated with the processes as described above may be stored in the ROM 610 and/or the RAM 615. Optionally, the program instructions may be stored on a tangible computer readable medium such as a compact disk, a digital disk, flash memory, a memory card, a USB drive, an optical disc storage medium, such as a Blu-ray™ disc, and/or other recording medium.

An optional display interface 630 may permit information from the bus 600 to be displayed on the display 635 in audio, visual, graphic or alphanumeric format. Communication with external devices may occur using various communication ports 640. A communication port 640 may be attached to a communications network, such as the Internet or a local area network.

The hardware may also include an interface 645 which allows for receipt of data from input devices such as a keyboard 650 or other input device 655 such as a mouse, a joystick, a touch screen, a remote control, a pointing device, a video input device and/or an audio input device.

It should be noted that printing devices as described above are provided by way of example only. The techniques and processes as taught herein may be applied to additional devices that have varying levels of power consumption based upon their state of operation.

Various of the above-disclosed and other features and functions, or alternatives thereof, may be combined into many other different systems or applications. Various presently unforeseen or unanticipated alternatives, modifications, variations or improvements therein may be subsequently made by those skilled in the art, each of which is also intended to be encompassed by the disclosed embodiments.

What is claimed is:

1. A method of polling a device comprising:
sending, by a processing device, a first polling request to a device to be polled after an elapsed first period of time;
receiving, at the processing device, a first polling response from the device to be polled;
determining, by the processing device, a mode the device to be polled is currently operating in based upon the first polling response; and
if the device to be polled is operating in a high power state, sending, by the processing device, a second polling request to the device to be polled after an elapsed second period of time, wherein the second period of time is shorter than the first period of time.

2. The method of claim 1, further comprising:
receiving, at the processing device, a second polling response from the device to be polled;
determining, by the processing device, a mode the device to be polled is currently operating in based upon the second polling response; and
if the device to be polled is operating in a high power state, sending, by the processing device, a third polling request to the device to be polled after an elapsed second period of time.

3. The method of claim 1, wherein sending a first polling request further comprises requesting power state log information for the device to be polled, wherein the power state log information comprises information related to what mode the device to be polled in operated in during the first period of time, and how long the device to be polled operating in each mode during the first period of time.

4. The method of claim 3, further comprising determining, by the processing device, power log information for the device to be polled, wherein the power log information comprises a representation of total power used by the device to be polled during the first period of time.

5. The method of claim 4, further comprising determining, by the processing device, an average power consumed by the device to be polled during the first period of time based upon the determined total power used.

6. The method of claim 1, wherein the second period of time is determined by the processing device based upon historic information related to operation of the device to be polled.

7. The method of claim 1, wherein the device to be polled is a printing device.

8. The method of claim 7, wherein a high power state comprises a print mode.

9. The method of claim 7, wherein a low power state comprises at least one of an idle mode or a sleep mode.

10. A system for polling a device comprising:
a processing device; and
a non-transitory computer readable medium in communication with the processing device, the computer readable medium comprising one or more programming instructions for causing the processing device to:
send a first polling request to a device to be polled after an elapsed first period of time,
receive a first polling response from the device to be polled,
determine a mode the device to be polled is currently operating in based upon the first polling response, and
if the device to be polled is operating in a high power state, send a second polling request to the device to be polled after an elapsed second period of time, wherein the second period of time is shorter than the first period of time.

11. The system of claim 10, further comprising one or more programming instructions for causing the processing device to:
receive a second polling response from the device to be polled;
determine a mode the device to be polled is currently operating in based upon the second polling response; and
if the device to be polled is operating in a high power state, send a third polling request to the device to be polled after an elapsed second period of time.

12. The system of claim 10, wherein the one or more instructions for sending a first polling request further comprise instructions for causing the processing device to request power state log information for the device to be polled, wherein the power state log information comprises information related to what mode the device to be polled in operated in during the first period of time, and how long the device to be polled operating in each mode during the first period of time.

13. The system of claim 12, further comprising one or more programming instructions for causing the processing device to determine power log information for the device to be polled, wherein the power log information comprises a representation of total power used by the device to be polled during the first period of time.

14. The device of claim 13, further comprising one or more programming instructions for causing the processing device to determine an average power consumed by the device to be polled during the first period of time based upon the determined total power used.

15. The device of claim 10, wherein the second period of time is determined by the processing device based upon historic information related to operation of the device to be polled.

16. The device of claim 10, wherein the device to be polled is a printing device.

17. The device of claim 16, wherein a high power state comprises a print mode.

18. The device of claim 16, wherein a low power state comprises at least one of an idle mode or a sleep mode.
